(19) United States
(12) Patent Application Publication
(10) Pub. No.: US 2026/0002961 A1
(43) Pub. Date: Jan. 1, 2026

(54) Metal Plated Conductive Elastomer Sort Probe

(71) Applicant: Intel Corporation, Santa Clara, CA (US)

(72) Inventor: Chandru PERIASAMY, Portland, OR (US)

(21) Appl. No.: 18/755,763

(22) Filed: Jun. 27, 2024

(51) Int. Cl. G01R 1/067; G01R 1/073; G01R 3/00

(52) U.S. Cl. CPC G01R 1/06716; G01R 1/06761; G01R 1/07314; G01R 3/00

(57) ABSTRACT

According to the various aspects, a testing probe may include an electrically conductive pad disposed on a substrate with an electrically conductive elastomer head disposed on the electrically conductive pad and a metal layer disposed on the electrically conductive elastomer head. In an aspect, a plurality of the testing probes are disposed on the substrate to form a probe head interposer.

### BACKGROUND

For integrated circuit design and fabrication, the need to improve manufacturing processes and lower costs are constant challenges. Various testing techniques are used during the semiconductor manufacturing process, such as functional testing for the basic functions of integrated circuits (ICs), structural testing for identifying physical defects, parametric testing for analyzing performance of a die under varying conditions, and reliability testing for assessing the durability and longevity of the die. The process of electrically testing semiconductor dies to determine if each die is functioning properly is one of the most important processes in semiconductor manufacturing.

The automatic test equipment that does the testing typically includes an IC tester, the test head, and the test head manipulator. A probe card is mounted on the test head and is electrically connected to the IC tester. The probe card will have a plurality of probe heads that provide the means to conduct electrical signals from the tester to the semiconductor die. The manufacturing costs of conventional probe heads are quite expensive and it would be desirable to provide a probe head design that has lower manufacturing costs and is durable and easy to repair and/or replace.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIGS. 1A and 1B show exemplary representations of a probe head interposer with metal-plated conductive elastomer sort probes according to an aspect of the present disclosure;

FIGS. 2 and 2A show cross-sectional views of an exemplary representation of a probe head interposer according to an aspect of the present disclosure;

FIGS. 3A through 3E show exemplary representations of the intermediate structures during the manufacture of a probe head interposer according to an aspect of the present disclosure;

FIG. 4 shows an exemplary representation of a probe head interposer attached to a probe card and tester head according to an aspect of the present disclosure;

FIGS. 5 and 5A show exemplary representations of an attachment member for a probe head interposer according to an aspect of the present disclosure;

FIG. 6 shows an exemplary representation of a probe head interposer attached to a probe card according to another aspect of the present disclosure; and

FIG. 7 shows a simplified flow diagram for an exemplary method according to an aspect of the present disclosure.

### DETAILED DESCRIPTION

The following detailed description refers to the accompanying drawings that show, by way of illustration, specific details, and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects can be combined with one or more other aspects to form new aspects.

According to the present disclosure, a present metal-plated conductive elastomer probe head and interposer structures may include a ceramic or organic substrate with metal columns or vias, land grid array pads positioned on both ends of the via and connecting the pads, and an electrically conductive elastomer head with a plated metal cap formed on the pad.

In an aspect, the present electrically conductive elastomer heads will be deposited on the pads, which may be made of copper, using a pico-liter dispenser or by a screen printing technique. The electrically conductive elastomer head may extend above the surface of the substrate and have a height in the range of approximately 15 to 500 microns. In addition, the electrically conductive elastomer head may have a circular footprint that is approximately 50 to 95 percent smaller in diameter relative to the pad. The pads may have a diameter in the range of approximately 20 to 500 microns. The uncured electrically conductive elastomer heads may be held between two precisely machined flat hot plates of a press tool to planarize, i.e., flattened, and cure the electrically conductive elastomer heads. The interposer may then be electroplated with gold that would be deposited over the electrically conductive elastomer heads and any exposed portion of the pads, thereby creating a continuous highly conductive electrical path between the two sides of the interposer.

The present disclosure provides a testing probe including an electrically conductive pad disposed on a substrate, an electrically conductive elastomer head disposed on the electrically conductive pad, and a metal layer disposed on the electrically conductive elastomer head, wherein the testing probe is coupled to a probe card printed circuit board.

The present disclosure is further directed to a probe head interposer (also referred to as an interposer herein) including a substrate having a land grid array of probes. The probes include a plurality of electrically conductive pads, an electrically conductive elastomer head disposed on each of the plurality of electrically conductive pads, and a metal layer deposited on the electrically conductive elastomer head that is disposed on each of the plurality of electrically conductive pads. The interposer is coupled to a probe card printed circuit board of a test equipment.

The present disclosure is also directed to a method that includes providing a substrate, forming an electrically conductive pad on the substrate, depositing an electrically conductive elastomer head on the electrically conductive pad, planarizing and curing the electrically conductive elastomer heads, and depositing a metal layer disposed on the electrically conductive elastomer head to form a testing probe, and coupling the test probe to a probe card printed circuit board. In an aspect, the electrically conductive elastomer head may be planarized and cured before depositing the metal layer, which may be electroplated gold.

The technical advantages of the present disclosure include, but are not limited to:
(i) providing a sorting probe that is simpler to manufacture, i.e., use of a pico-liter dispenser or screen printing to form the probe head made of an electrically conductive elastomer and the use of conventional copper vias;
(ii) providing a sorting probe that is made with a less expensive material, i.e., a conductive elastomer; and
(iii) providing the ability to rework/repair a probe head interposer given the simpler manufacturing process.

To more readily understand and put into practical effect the present probe head interposer and methods, which may provide improved costs for sort testing, particular aspects will now be described by way of examples provided in the drawings that are not intended as limitations. The advantages and features of the aspects herein disclosed will be apparent through reference to the following descriptions relating to the accompanying drawings. Furthermore, it is to be understood that the features of the various aspects described herein are not mutually exclusive and can exist in various combinations and permutations. For the sake of brevity, duplicate descriptions of features and properties may be omitted.

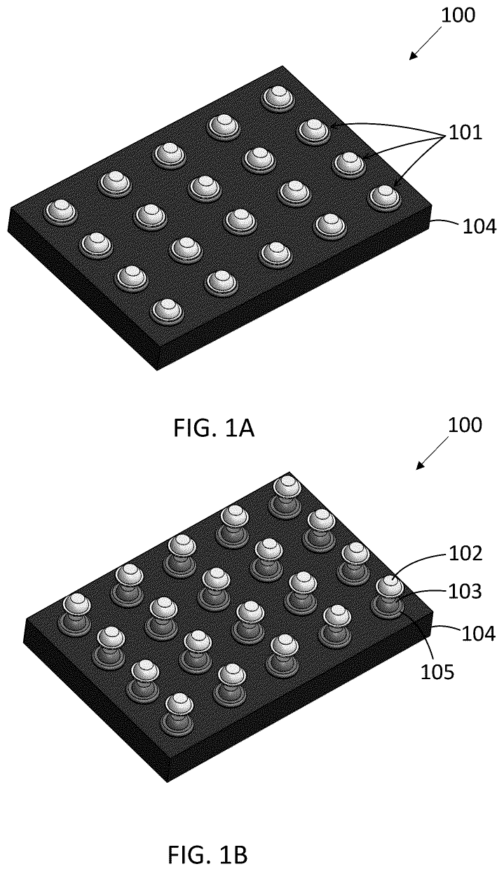

FIGS. 1A and 1B show exemplary representations of a probe head interposer 100 according to an aspect of the present disclosure. As shown in FIG. 1A, the probe head interposer 100 may have a plurality of probes 101 that are formed in a substrate 104. As shown in FIG. 1B, each of the plurality of probes may have a metal layer 102, e.g., gold cap, formed over a dome-shaped electrically conductive elastomer head 103 that is positioned over an electrically conductive pad 105, e.g., a copper pad. In an aspect, the substrate 104 may be made of a ceramic or organic substrate material. In another aspect, the electrically conductive elastomer head may be made of a silicone material impregnated with metal particles.

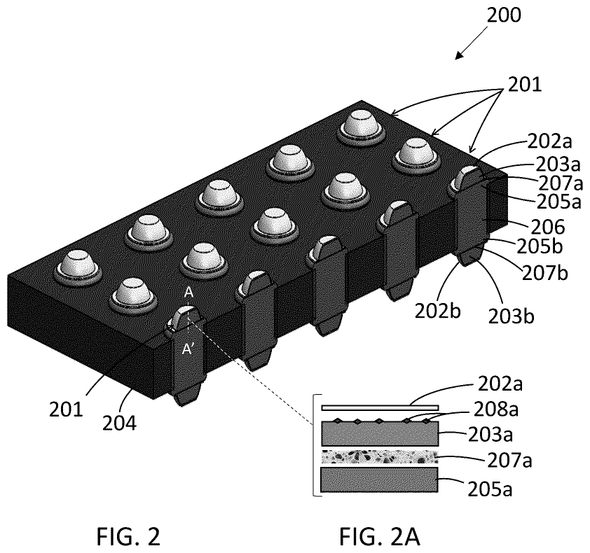

FIGS. 2 and 2A show cross-sectional views of an exemplary representation of a probe head interposer 200 according to an aspect of the present disclosure. As shown in FIG. 2, the probe head interposer 200 may have a plurality of probes 201 that are formed in a substrate 204. In an aspect, each of the probes 201 may include a via 206 having a first end and a second end. The via 206 may be made of a copper material or other high-conducting metal. In another aspect, the probes 201 may be symmetrical so that the first end may have a first conductive pad 205a, a first layer of hollow glass microspheres or silicone microbubbles 207a, a first electrically conductive elastomer head 203a and a first metal layer 202a, and the second end may have a second conductive pad 205b, a second layer of silicone microbubbles 207b, a second electrically conductive elastomer head 203b and a second metal layer 202b.

In FIG. 2A, a view along a section line A-A′ of the probe 201 shows expanded the first conductive pad 205a, the first layer of silicone microbubbles 207a, the first electrically conductive elastomer head 203a, which may optionally have embedded metal particles 208a (e.g., tungsten particles), and the first metal layer 202a (e.g., a gold capping layer).

In this aspect, a layer of silicone microbubbles may be optionally provided to modulate, i.e., lower, the stiffness of the probe 201. After the first electrically conductive elastomer head 203a is planarized and cured, the silicone microbubbles 207a are encapsulated by the first electrically conductive elastomer head 203a. In another aspect, if hollow glass microspheres are used, they may be crushed by a mechanical load to lower the probes' stiffness.

In another aspect, when a die is provided with copper solder bumps, the use of metal particles 208a that are embedded in a top surface of each of the electrically conductive elastomer heads may offer a better contact surface with the copper solder bumps, especially when a copper oxide film may be present on the copper solder bumps.

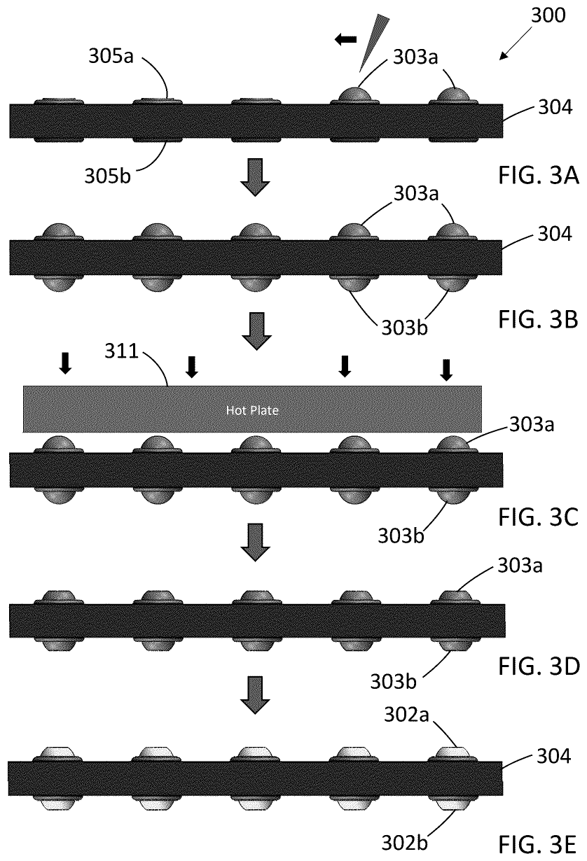

FIGS. 3A through 3E show exemplary representations of the intermediate structures during the manufacture of a probe head interposer 300 according to an aspect of the present disclosure. In FIG. 3A, a substrate 304 may be provided having a first plurality of conductive pads 305a forming a first land grid array (LGA) on a first surface and a second plurality of conductive pads 305b forming a second LGA on a second surface, with vias connecting them (not shown). In this aspect, a first plurality of conductive elastomer heads 303a may be formed on the plurality of conductive pads 305a, for example, using one or more pico-liter dispensers 310. Alternatively, a screen printing process may be used to form a plurality of conductive elastomer heads.

Similarly, as shown in FIG. 3B, a second plurality of conductive elastomer heads 303b may be formed on the second plurality of conductive pads 305b, whereby the first and second surfaces of the probe head interposer 300 are symmetrical.

In FIG. 3C, a pressing tool (not shown) having a movable hot plate 311 may be used to planarize and thermally cure (i.e., harden) the first plurality of elastomer heads 303a, while the second plurality of elastomer heads 303b may be planarized and cured on a heated support plate (not shown) in the pressing tool upon which the probe head interposer 300 may be placed. The planarized and cured first plurality of elastomer heads 303a and second plurality of elastomer heads 303b are shown in FIG. 3D.

In FIG. 3E, the planarized and cured first plurality of elastomer heads 303a and second plurality of elastomer heads 303b may be provided with metal capping layers 302a and 302b, respectively, made of gold. The gold capping layers may be, for example, plated onto the first plurality of elastomer heads 303a and second the plurality of elastomer heads 303b using a wet or dry electrolytic process. In an aspect, a layer of masking or sacrificial material may be deposited between the first plurality of elastomer heads 303a and the second plurality of elastomer heads 303b to prevent the deposition of unwanted material that may cause unwanted short circuits.

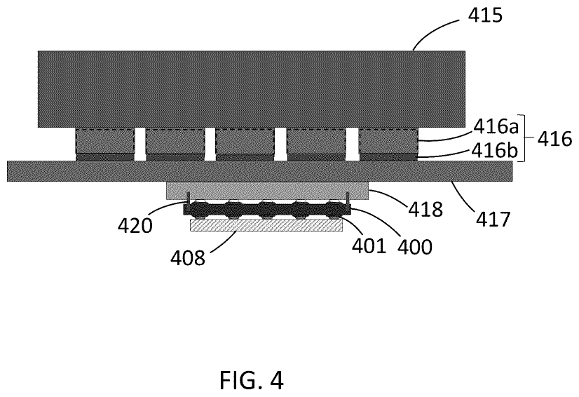

FIG. 4 shows an exemplary representation of a probe head interposer 400 attached to a probe card printed circuit board (PCB) 417 positioned on a tester head 415 of a testing tool (not shown), according to an aspect of the present disclosure. In this aspect, a probe head interposer 400 may have a plurality of probes 401 that are brought into engagement with a device under test 409, i.e., a die in a wafer, for sort testing.

In this aspect, the probe head interposer 400 may be attached by a plurality of attachment members 420 to a space transformer 418, which may have traces and micro-vias (both not shown) to shrink the electrical routings and convey electrical signals between the probe card PCB 417 and the device under test 409. In another aspect, while there are two attachment members 420 shown in FIG. 4, it is preferred that at least three attachment members 420 be used. The probe card PCB 417 may be detachably joined to the tester head 415 by a plurality of connectors 416, which, for example, may have a socket member 416a attached to the tester head 415 and plug member 416b attached to the probe card, as shown in FIG. 4.

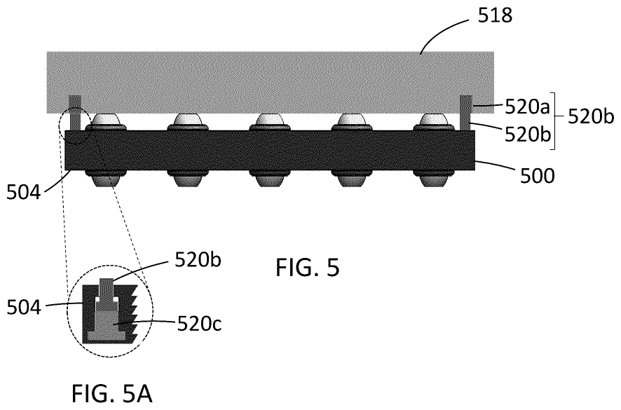

FIGS. 5 and 5A show exemplary representations of attachment members 520 for a probe head interposer 500 according to an aspect of the present disclosure. In this aspect, the probe head interposer 500 may be attached by the attachment members 520 to a space transformer 518. The attachment members 520 may have a first magnet 520a, which is embedded in the probe head interposer 500, and a second magnet 520b, which is embedded in the space transformer 518. The first magnet 520a and second magnet 520b may be self-aligning and allow easy assembly with and disassembly of the probe head interposer 500 from the space transformer 518. As shown in FIG. 5A, the attachment members 520 may have the first magnet 520a embedded in a substrate 504 and rest on a block 520c when it is not engaged.

It should be understood that a variety of different attachment members may be used to attach a probe head interposer to a space transformer, including clips, screws, inserts, and other fastening devices.

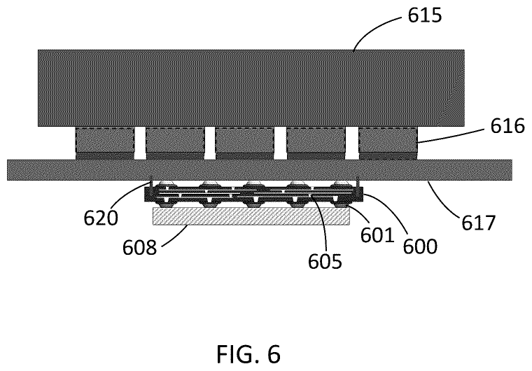

FIG. 6 shows an exemplary representation of a probe head interposer 600 attached directly to a probe card printed circuit board (PCB) 617, which is positioned on a tester head 615 of a testing tool (not shown), according to an aspect of the present disclosure. The probe card PCB 617 may be detachably joined to the tester head 615 by a plurality of socket connectors 616. In this aspect, the probe head interposer 600 may have a plurality of probes 601 that are brought into engagement with a device under test 609, i.e., a die, for sort testing. In addition, the probe head interposer 600 may have a plurality of traces and micro-vias 609 to convey electrical signals between the probe card PCB 617 and the device under test 609. In this aspect, the probe head interposer 600 may be attached by a plurality of attachment members 620 to the probe card PCB 617 In another aspect, while there are two attachment members 620 shown in FIG. 6, it is preferred that at least three attachment member 620 be used.

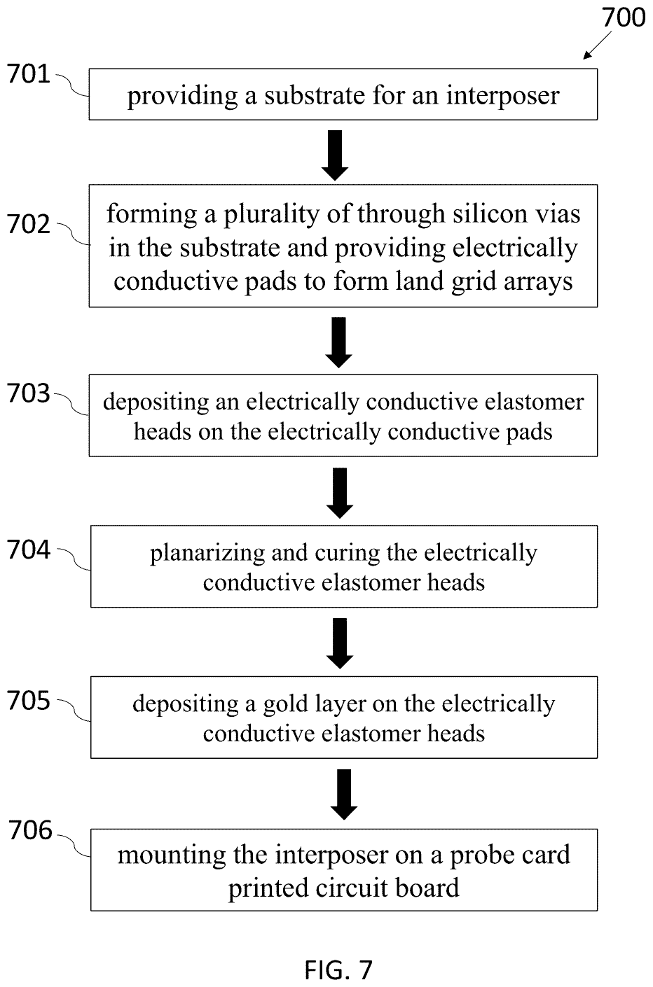

FIG. 7 shows a simplified flow diagram for an exemplary method 700 according to an aspect of the present disclosure.

The operation 701 may be directed to providing a substrate for an interposer.

The operation 702 may be directed to forming a plurality of vias in the substrate and providing electrically conductive pads to form land grid arrays.

The operation 703 may be directed to depositing electrically conductive elastomer heads on the electrically conductive pads.

The operation 704 may be directed to planarizing and curing the electrically conductive elastomer heads.

The operation 705 may be directed to depositing a gold layer on the electrically conductive elastomer heads.

The operation 706 may be directed to mounting the interposer on a probe card printed circuit board.

It will be understood that any property described herein for a particular metal-plated conductive elastomer sort/testing probe and method for making this testing probe may also hold for any probe head interposer using the present metal-plated conductive elastomer sort probe described herein. It will also be understood that any property described herein for a specific method may hold for any of the methods described herein. Furthermore, it will be understood that for any particular metal-plated conductive elastomer sort/testing probe and the methods described herein, not necessarily all the components, materials, or operations described will be shown in the accompanying drawings or method, but only some (not all) components or operations may be disclosed.

To more readily understand and put into practical effect the probe head interposer having present metal plated conductive elastomer sort/testing probe, they will now be described by way of examples. For the sake of brevity, duplicate descriptions of features and properties may be omitted.

### EXAMPLES

Example 1 provides for a testing probe including an electrically conductive pad disposed on a substrate, an electrically conductive elastomer head disposed on the electrically conductive pad, and a metal layer disposed on the electrically conductive elastomer head, for which the testing probe is coupled to a probe card printed circuit board.

Example 2 may include the testing probe of example 1 and/or any other example disclosed herein, for which the electrically conductive pad is composed of a copper material.

Example 3 may include the testing probe of example 1 and/or any other example disclosed herein, for which the electrically conductive elastomer head includes a silicone material impregnated with metal particles.

Example 4 may include the testing probe of example 1 and/or any other example disclosed herein, for which the metal layer is composed of a gold material.

Example 5 may include the testing probe of example 1 and/or any other example disclosed herein, which further includes a via disposed in the substrate, for which the via includes a first end and a second end, and for which the first end of the via is proximally disposed on a first surface of the substrate and the second end of the via is proximally disposed on a second surface of the substrate.

Example 6 may include the testing probe of example 5 and/or any other example disclosed herein, for which the electrically conductive pad includes a first electrically conductive pad and a second electrically conductive pad, for which the first electrically conductive pad is located at the first end of the via and the second electrically conductive pad is located at the second end of the via.

Example 7 may include the testing probe of example 5 and/or any other example disclosed herein, for which the via is composed of a copper material.

Example 8 may include the testing probe of example 1 and/or any other example disclosed herein, which further includes a layer of hollow glass microspheres or silicone microbubbles disposed on the pad.

Example 9 may include the testing probe of example 1 and/or any other example disclosed herein, which further includes a plurality of metal particles embedded in a top surface of the electrically conductive elastomer head.

Example 10 provides for an interposer that includes a substrate including a land grid array of probes, for which the probes comprise a plurality of electrically conductive pads, an electrically conductive elastomer head disposed on each of the plurality of electrically conductive pads, and a metal layer deposited on the electrically conductive elastomer heads disposed on the plurality of electrically conductive pads, for which the interposer is coupled to a probe card printed circuit board.

Example 11 may include the interposer of example 10 and/or any other example disclosed herein, for which the plurality of electrically conductive pads are composed of a copper material.

Example 12 may include the interposer of example 10 and/or any other example disclosed herein, for which the electrically conductive elastomer head includes a silicone material impregnated with metal particles.

The interposer of claim 10, for which the metal layer is composed of a gold material.

Example 14 may include the interposer of example 10 and/or any other example disclosed herein, for which the land grid array of probes further includes a plurality of vias disposed in the substrate, for which each of the vias includes a first end and a second end, and for which the first end of the via is proximally disposed on a first surface of the substrate and the second end of the via is proximally disposed on a second surface of the substrate, and for which the via is composed of a copper material.

Example 15 may include the interposer of example 14 and/or any other example disclosed herein, for which the plurality of electrically conductive pads includes a first plurality of pads and a second plurality of pads, for which the first plurality of pads is proximally located at the first end of the via and the second plurality of pads is proximally located at the second end of the via.

Example 16 may include the interposer of example 10 and/or any other example disclosed herein, which further includes a plurality of metal particles embedded in a top surface of each of the electrically conductive elastomer heads.

Example 17 may include the interposer of example 10 and/or any other example disclosed herein, which further includes a plurality of traces and micro-vias disposed in the substrate that is coupled to the plurality of electrically conductive pads.

Example 18 may include the interposer of example 10 and/or any other example disclosed herein, which further includes a plurality of attachment members for attaching the substrate to a space transformer or a probe card PCB.

Example 19 provides a method including providing a substrate, forming an electrically conductive pad on the substrate, depositing an electrically conductive elastomer head on the electrically conductive pad, and depositing a metal layer disposed on the electrically conductive elastomer head to form a testing probe, and coupling the testing probe to a probe card printed circuit board.

Example 20 may include the method of example 19 and/or any other example disclosed herein, which further includes planarizing and curing the electrically conductive elastomer head before depositing the metal layer.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) herein may be understood as electrically coupled or as mechanically coupled, e.g., attached or fixed or attached, or just in contact without any fixation, and it will be understood that both direct coupling or indirect coupling (in other words: coupling without direct contact) may be provided.

The terms “and” and “or” herein may be understood to mean “and/or” as including either or both of two stated possibilities.

While the present disclosure has been particularly shown and described with reference to specific aspects, it should be understood by those skilled in the art that various changes in form and detail may be made therein without departing from the spirit and scope of the present disclosure as defined by the appended claims. The scope of the present disclosure is thus indicated by the appended claims and all changes which come within the meaning and range of equivalency of the claims are therefore intended to be embraced.

What is claimed is:

1. A testing probe comprising:
an electrically conductive pad disposed on a substrate;
an electrically conductive elastomer head disposed on the electrically conductive pad; and
a metal layer disposed on the electrically conductive elastomer head, wherein the testing probe is coupled to a probe card printed circuit board.

2. The testing probe of claim 1, wherein the electrically conductive pad is composed of a copper material.

3. The testing probe of claim 1, wherein the electrically conductive elastomer head comprises a silicone material impregnated with metal particles.

4. The testing probe of claim 1, wherein the metal layer is composed of a gold material.

5. The testing probe of claim 1, further comprises a via disposed in the substrate, wherein the via comprises a first end and a second end; and
wherein the first end of the via is proximally disposed on a first surface of the substrate and the second end of the via is proximally disposed on a second surface of the substrate.

6. The testing probe of claim 5, wherein the electrically conductive pad comprises a first electrically conductive pad and a second electrically conductive pad, wherein the first electrically conductive pad is located at the first end of the via and the second electrically conductive pad is located at the second end of the via.

7. The testing probe of claim 5, wherein the via is composed of a copper material.

8. The testing probe of claim 1, further comprises a layer of hollow glass microspheres or silicone microbubbles disposed on the pad.

9. The testing probe of claim 1, further comprises a plurality of metal particles embedded in a top surface of the electrically conductive elastomer head.

10. An interposer comprising:
a substrate comprising a land grid array of probes, wherein the probes comprise:
a plurality of electrically conductive pads;
an electrically conductive elastomer head disposed on each of the plurality of electrically conductive pads; and
a metal layer deposited on the electrically conductive elastomer heads disposed on the plurality of electrically conductive pads, wherein the interposer is coupled to a probe card printed circuit board.

11. The interposer of claim 10, wherein the plurality of electrically conductive pads are composed of a copper material.

12. The interposer of claim 10, wherein the electrically conductive elastomer head comprises a silicone material impregnated with metal particles.

13. The interposer of claim 10, wherein the metal layer is composed of a gold material.

14. The interposer of claim 10, wherein the land grid array of probes further comprises a plurality of vias disposed in the substrate, wherein each of the vias comprises a first end and a second end; and
wherein the first end of the via is proximally disposed on a first surface of the substrate and the second end of the via is proximally disposed on a second surface of the substrate, and wherein the via is composed of a copper material.

15. The interposer of claim 14, wherein the plurality of electrically conductive pads comprises a first plurality of pads and a second plurality of pads, wherein the first plurality of pads is proximally located at the first end of the via and the second plurality of pads is proximally located at the second end of the via.

16. The interposer of claim 10, further comprises a plurality of metal particles embedded in a top surface of each of the electrically conductive elastomer heads.

17. The interposer of claim 10, further comprises a plurality of traces and micro-vias disposed in the substrate that are coupled to the plurality of electrically conductive pads.

18. The interposer of claim 10, further comprises a plurality of attachment members for attaching the substrate to a space transformer or a probe card PCB.

19. A method comprising:
providing a substrate;
forming an electrically conductive pad on the substrate;
depositing an electrically conductive elastomer head on the electrically conductive pad;
depositing a metal layer disposed on the electrically conductive elastomer head to form a testing probe; and
coupling the testing probe to a probe card printed circuit board.

20. The method of claim 19, further comprises planarizing and curing the electrically conductive elastomer head before depositing the metal layer.
